(19) United States
(12) Patent Application Publication
(10) Pub. No.: US 2006/0043979 A1
(43) Pub. Date: Mar. 2, 2006

(54) Emi measuring method and its system

(76) Inventor: Wei Wu, Zhejiang (CN)

Correspondence Address: HARNESS, DICKEY & PIERCE, P.L.C., P.O. BOX 8910, RESTON, VA, 20195, US

(21) Appl. No.: 10/530,704

(22) PCT Filed: Dec. 15, 2003
(86) PCT No.: PCT/CN03/01064

§ 371 Date: Apr. 8, 2005

(30) Foreign Application Priority Data
Dec. 16, 2002 (CN) 02156282.2

(51) Int. Cl. G01R 27/28

(52) U.S. Cl. 324/627

(57) ABSTRACT

An electromagnetic interference (EMI) measuring method and its system for diagnosing EMI of various electronic devices and instructing user to improve design to satisfy Electromagnetic Compatibility (EMC) criterion. The measuring method according to the present invention includes acquiring a set of time domain signal waveforms from a group of uniformly distributed test points on equipment under test (EUT), and then processing, converting, comparing and analysing, and finally determining physical position of EMI on EUT. To implement the present method, the present invention provides an EMI measuring system. The system includes signal acquisition portion and signal analysis portion. The signal analysis portion takes computer as carrier, which establishes processing, converting, comparing and analysing modules on operating system platform of computer. The method steps and system structure according to the present invention are simple and convenient which are no restricted by ambience and the measuring result is reliable.

### FIELD OF THE INVENTION

The present invention relates to an Electromagnetic Interference (EMI) measuring method and its system.

### BACKGROUND OF THE INVENTION

The level of Electromagnetic Interference (EMI) or its ability of anti-electromagnetic-interference is a very important parameter to evaluate an electronic product. With the enforcement of the Electromagnetic Compatibility (Amendment) Regulations 1995 (EMCR) in 1996, all the electromagnetic products must meet the Europe EMCR requirement before being sold in Europe market. China also issued its Electromagnetic Compatibility (EMC) criterion in 2001. EMC diagnosis, however, requires high technology, which sometimes is more sophisticated than the manufacture itself. As the EMC status of a new product is unforeseeable, it is normal for a product to fail the EMC test after its prototype is ready and goes to EMC lab for test. The prototype has to be returned to workshop for modification. Usually, the prototype has to be reproduced as the Printed Circle Board inside the prototype is mostly unchangeable. If the prototype fails the EMC test in EMC lab again, new modification has to be made until the prototype finally passes the EMC test. On the other hand, even if products have met the requirement of EMC regulations, any change in product layout caused by improving design and any replacement in component caused by altering the component supplier will make retest necessary again.

The prior art can only determine if the Equipment Under Test (EUT) has met the EMC criterion. When the EUT fails the EMC test, the prior art can only report whether the EMI of the EUT is higher than EMC limitation under a specific frequency, rather than locating the EMI in the EUT. It is very difficult to trace out the source of EMI and remove it. To locate EMI in the EUT mainly depends on the experience of the design engineer and continuous trying. In addition, the standard EMC test can only be carried out in shielded chamber with expensive equipments and the above test-modification-test looping can cause massive increase in the cost and make the product R&D period unforeseeable.

### SUMMARY OF THE INVENTION

The present invention provides an Electromagnetic Interference (EMI) measuring method and its system for diagnosing EMI of various electronic devices and instructing the user to improve the design to satisfy EMC criterion. The principle of the method is that one can measure directly in EUT layout a group of equably distributed test points or simulate the EUT using the Electronic Design Assistant software (such as SPICE, PROTEL or other CAD software) to obtain a set of time-domain signal waveform data that can be in the form of the current, or the voltage, or the electromagnetic field intensity when the EMI is over limitation under a specialized frequency or evaluation under a specialized frequency is desired. Then, one can number the waveform data according to the test point locations and convert the time-domain signal into the frequency-domain signal. By comparing the value of the EMI under the specialized frequency, waveform data bearing the maximum EMI can be traced out. As all the waveform data are numbered corresponding to the specialized test points, it is also easy to trace out the physical location of the test point bearing the maximum EMI value. Meanwhile, one can trace the EMI location in the signal waveform by means of time/frequency analysis. Because the different parts in a signal waveform are generated by different components in the circuit, it is possible to deduce the components that generate the EMI in the different parts of the waveform. One can reduce EMI by modifying the layout where the EMI is located, or by replacing the components that generate EMI until the EUT finally accords with EMC criterion.

The above-mentioned invention can be implemented as below.

(1) The EMI diagnosis method comprising:

First, a group of time-domain waveforms are acquired by measuring a group of equably distributed test points that are well numbered. Second, processing, converting, comparing and analysing the waveforms can trace out the test point bearing the maximum EMI under a specified frequency. The position where the test point located should be the location of the EMI source.

(2) The EMI diagnosis system:

To implement the method above, the present invention provides an EMI measuring system. The system consists of two major portions including the signal acquisition portion and the signal analysis portion. The signal acquisition portion includes probe and waveform-record-circuit. The signal analysis portion that disposed in a computer includes the data input interface, the memory, and the time/frequency converter and frequency component comparator installed in the computer operation system platform.

Compared with prior art, the present invention method and its system have prominent advantages. By means of tracing out EMI physical position and tracing out components that possibly generate EMI, the invention method and its system indicate a right approach for reducing EMI and shorten the product developing period. The computer based processing, converting, comparing and analysing system are flexible and independent from the ambience and working condition. It can also acquire EMI data for analysis under normal industry environment with general instruments. Compared with prior art that requires expensive frequency analyser and shield chamber, the present invention is a money-saving solution. The present invention is simple both in method and in system structure and easy to operate. The operation is independent from the environment and the diagnosis result is accurate.

### BRIEF DESCRIPTION OF THE DRAWING

FIG. 1 is a flow chart of the EMI diagnosis method.

FIG. 2 is a diagram to illustrate the different points in EUT layout with their EMI values used to trace EMI location in EUT layout under a specific frequency.

FIG. 3 is a diagram to illustrate the original waveform of a test point and its time/frequency distribution, which is used to locate the EMI position in the waveform under the specialized frequency.

FIG. 4 is a schematic diagram of the EMI diagnosis system structure.

FIG. 5 is a flow chart of the time/frequency converter and frequency component comparator.

### DETAILED DESCRIPTION OF BEST MODE EMBODIMENTS

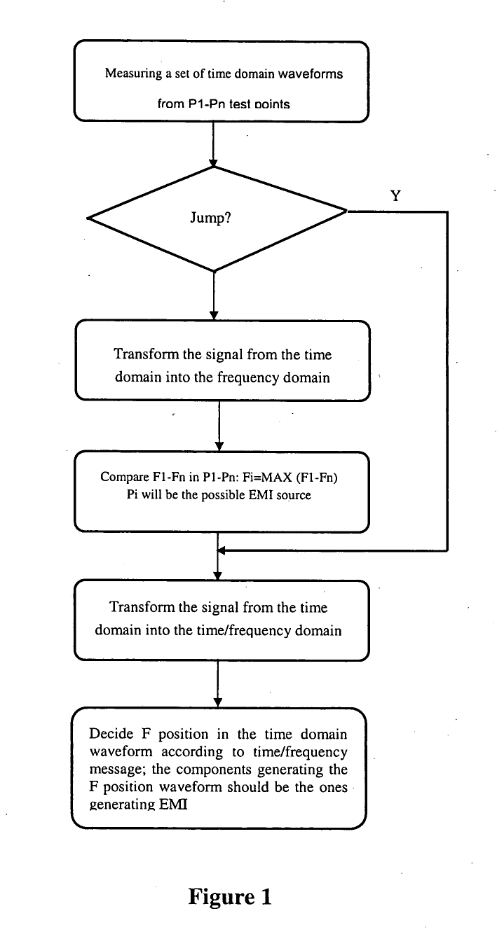

FIG. 1 is a flow chart of the EMI diagnosis method and the process of the invention method comprising:

(1) To obtain a set of time domain waveforms from a group of equably distributed test points (P1 . . . Pn) on an EUT. The waveform can be current waveform, or voltage waveform, or electromagnetic field intensity waveform.

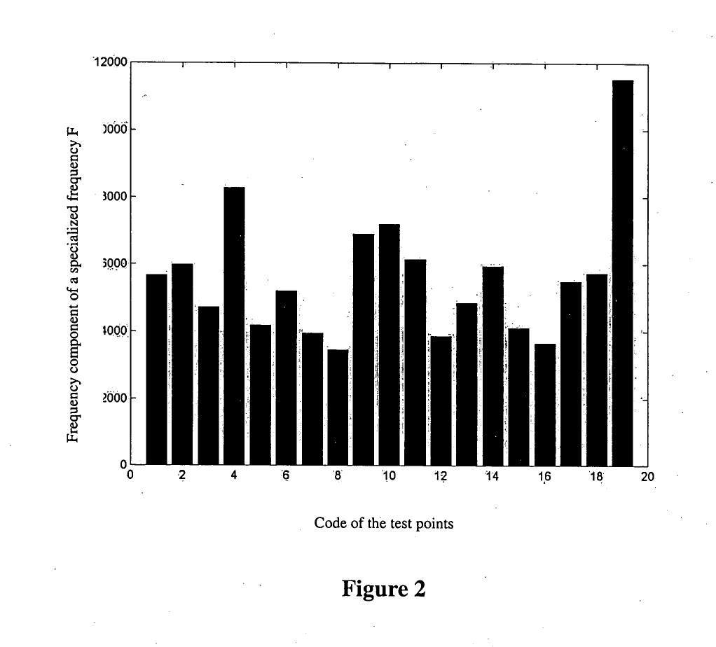

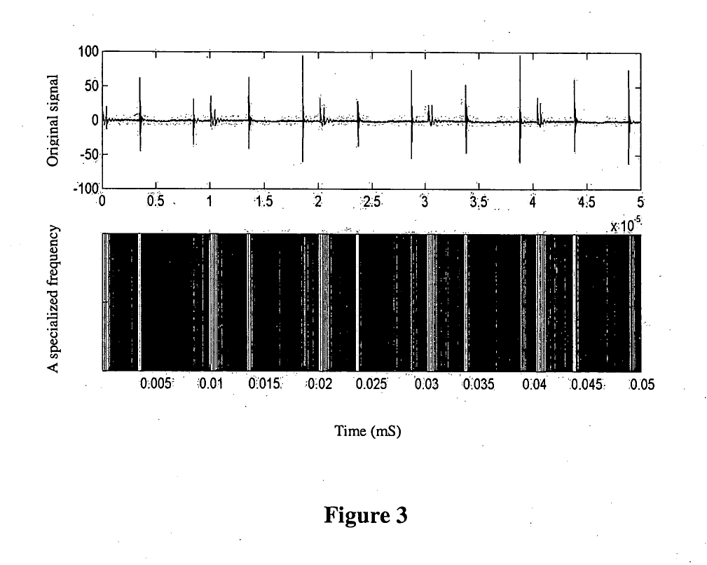

(2) To transform the above time-domain-signals into the frequency-domain-signals, as shown in FIG. 2. Alternatively, to transform the signals into time/frequency-domain-signals, as shown in FIG. 3.

The said “transforming the time-domain-signal into the frequency-domain-signal” can be achieved by means of Fourier Transform:

$$\hat{f} ( ω ) = {\int }_{- ∞}^{+ ∞} f ( t ) {ⅇ}^{- ⅈω t} ⅆ t$$

where
f(t) is the time domain signal being transformed;
\hat{f}(ω) is the spectrum after transforming;
Or by means of Wavelet Transform:

$$Wf ( u , s ) = < f , {ψ}_{u , s ,} >= {\int }_{- ∞}^{∞} f ( t ) \frac{1}{\sqrt{s}} {ψ}^{*} ( \frac{t - u}{s} ) ⅆ t$$
where
S is the scale factor;
U is the shifting factor;

$$ψ ( \frac{t - u}{s} )$$

is the basic wavelet function that depends on S and U;
* is the conjugate operation;
f(t) is the time domain signal being transformed; and
Wf(u, s) is the wavelet transform coefficient after transforming.

To transform time domain signal into time-frequency domain signal, one can use Wavelet Transform or Short Time Fourier Transform (STFT):

$$Sf ( u , ω ) = < f , {g}_{u , ω} >= {\int }_{- ∞}^{+ ∞} f ( t ) g ( t - u ) {ⅇ}^{- ⅈω t} ⅆ t$$

where
g(t−u) is the window function;
U is the shifting factor;
f(t) is the time domain signal being transformed; and
Sf(u, ω) is the STFT coefficient after transforming.

(3) To find out the test point bearing the maximum interference value by comparing the value of the EMI frequency components among test points according to above frequency analysis (FIG. 2); or to trace the EMI frequency locations in the time domain waveform according to the time/frequency domain analysis (FIG. 3).

(4) To trace out the position of the test point bearing the maximum EMI value in the EUT layout. The position will be the potential location of the EMI source. Alternatively, to find out the spots in the waveform in the time domain that corresponds to the moments when the EMI occurs. The electronic components in the EUT that generate the spots in the waveform should be the components generating the EMI.

As described above, suppose the EMI is known to be over limitation under the frequency F. To obtain the EMI value with the frequency F, one can first use an oscilloscope or the Electronic Design software (CAD to simulate EUT) to obtain P1-Pn point signal waveforms and record them. The recorded waveforms are transferred into the computer for processing. As shown in FIG. 2, after Fourier transforming or Wavelet transforming (using commercial software such as MATLAB mathematical software package or self designed software) we can obtain the F frequency EMI components F1-Fn corresponding to point P1-Pn. Comparing the n EMI components F1-Fn, the test point Pi that bears the maximum EMI value Fi can be found out and the Pi point should be the potential EMI source (in FIG. 2, there are P1-P19 test points and the Pi is P19). Because the Pi has been numbered according to its location in the EUT layout, it is easy to be mapped into physical location in the EUT layout. If the waveform is transformed from the time domain into the time/frequency domain by means of STFT or Wavelet Transform, as shown in FIG. 3, one can check out in which spot of the time domain waveform the frequency F (EMI) is generated according to the time distribution of frequency F, (in FIG. 3, EMI occurs in the time 4, 10, 13 . . . μs, corresponding to the spots of the time domain waveform where the amplitude of the waveform is not at its maximum value). In this way the spots of the time domain waveform that relate to EMI in time are well located and electronic components that generate the spots of the waveform should be the components that generate the EMI.

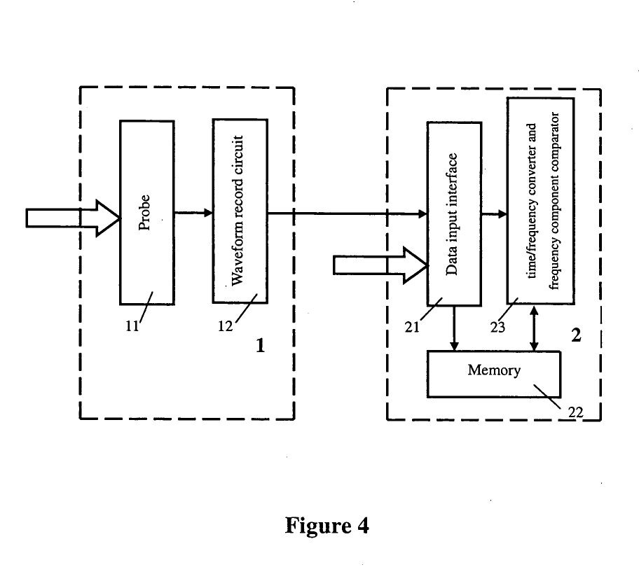

FIG. 4 is a schematic diagram of the diagnosis system structure. As shown in FIG. 4, the invention system consists of the signal acquisition portion (1) and the signal analysis portion (2). The signal acquisition portion (1) includes the probe (11) and the waveform recording circuit (12). The signal analysis portion (2) is based in a computer and includes the data input interface (21), the memory (22) and the time/frequency converter together with frequency component comparator (23).

The probe (11) is a measurement system that can pick up current, voltage, or electromagnetic field intensity waveform. In this application construction an oscilloscope probe is used as the probe.

The waveform record circuit (12) can be an oscilloscope waveform record circuit, or a A/D card plugged directly into the computer socket, or a A/D unit connected to the computer via a serial or parallel port of the data input interface (21).

The data input interference (21) is the I/O interface or the channel of the computer, or removable memory or disk, or computer memory or hard disk.

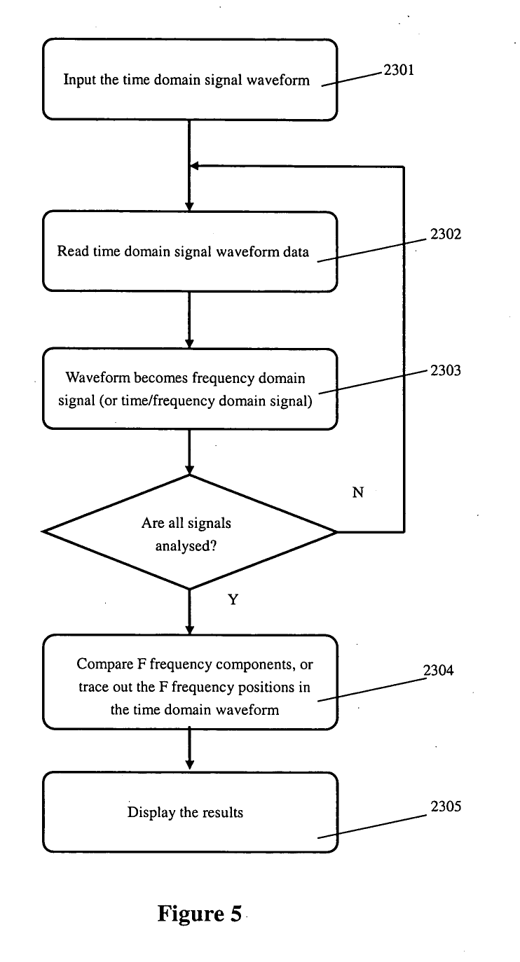

FIG. 5 shows the structure and flow chart of the time/frequency converter and frequency component comparator (23) of the signal analysis portion (2). The time/frequency converter and frequency component comparator (23) (C programming Language is used in this construction) are installed in the computer operation system (Windows 95/98/2000/XP or UNIX) platform, including a data input module (2301), a data acquisition module (2302), a signal transform module (2303), a frequency component comparison and analysis module (2304) and a display module (2305).

In the above construction, the time domain signal waveform acquired with the probe is recorded by the waveform record circuit (12) in the signal acquisition portion (1), and is delivered through the data input interface (21) of the signal analysis portion (2) into the memory (22) and the time/frequency converter and frequency component comparator (23), as shown in FIG. 5. The time domain signal waveform that reaches the time/frequency converter and frequency component comparator (23) is input via the data input module (2301), and collected by the data acquirement module (2302), and moved into the signal transform module (2303) where it is transformed by Fourier Transform, or Wavelet transform, or STFT into the frequency signal or time/frequency message. Then the signal after transforming is processed by the frequency component comparison and analysis module (2304) where the frequency components are ranked and traced out the maximum value, or the time domain signal is compared with time/frequency message. The processing results are finally displayed with the display module (2305).

1. An electromagnetic interference (EMI) measuring method comprising:
acquiring a set of time-domain waveforms from a group of equably distributed test points on an Equipment Under Test (EUT) and the test points are well numbered; and
processing, converting, comparing and analysing the waveforms, the test point bearing the maximum value under specified EMI frequency is traced out and the position where the test point located should be the location of the EMI source.

2. The method according to claim 1, further comprising:
obtaining a set of time domain signal waveforms from a group of equably distributed test points that are well numbered on the EUT;
processing the above set of time domain signal waveforms by transforming them into frequency domain or by transforming them into time/frequency domain;
comparing the EMI frequency components relating to each test point to trace out the test point bearing the maximum EMI; or tracing out the EMI frequency locations in the time domain waveform according to the time/frequency domain analysis; and
tracing out the position where the test point bearing the maximum EMI value in the EUT layout will be the potential EMI source location; alternatively, the electronic components in the EUT that generate the spots in the waveform should be the components generating the EMI by checking the different spots in the waveform in the time domain that correspond to the moments when the EMI occurs.

3. The method of claim 1, wherein the time domain waveform could be current waveform, or voltage waveform, electromagnetic field intensity waveform.

4. The method of claim 1, wherein the time-domain-signal-waveform is acquired by the measurement device, or electronic design software system.

5. The method of claim 1, wherein the time-domain-signals are transformed into the frequency-domain-signals by employing Fourier Transform or Wavelet Transform.

6. The method of claim 1, wherein the time-domain-signals are transformed into the time-frequency domain by employing Short Time Fourier Transform or Wavelet Transform.

7. An EMI measuring system comprising:
a signal acquisition portion, wherein the signal acquisition portion comprising the probe (11) and the waveform recording circuit (12); and
a signal analysis portion, wherein the signal analysis portion comprising the data input interface (21), the memory (22) and the time/frequency converter together with frequency component comparator (23).

8. The system of claim 7, wherein the data input interference (21) is the I/O interface and the channel of the computer, or removable memory or disk, or computer memory or hard disk.

9. The system of claim 7, wherein the time/frequency converter and frequency component comparator (23) are installed in the computer operation system platform and comprises a data input module (2301), a data acquirement module (2302), a signal transform module (2303), a frequency component comparison and analysis module (2304) and a display module (2305).

10. The system of claim 7, wherein the probe (11) is the measurement device that can pick up the current, the voltage, or the electromagnetic field intensity waveform.

11. The system of claim 7, wherein the waveform record circuit is the oscilloscope waveform record circuit, or the A/D card plugged directly in the computer socket, or the A/D unit connected to computer via serial or parallel port of the data input interface (21).

12. The method of claim 2, wherein the time domain waveform could be current waveform, or voltage waveform, electromagnetic field intensity waveform.

13. The method of claim 2, wherein the time-domain-signal-waveform is acquired by the measurement device, or electronic design software system.

14. The method of claim 2, wherein the time-domain-signals are transformed into the frequency-domain-signals by employing Fourier Transform or Wavelet Transform.

15. The method of claim 2, wherein the time-domain-signals are transformed into the time-frequency domain by employing Short Time Fourier Transform or Wavelet Transform.
